(19) United States
(12) Patent Application Publication
(10) Pub. No.: US 2026/0176741 A1
(43) Pub. Date: Jun. 25, 2026

(54) METHOD OF USING A TLE SYSTEM AND TLE SYSTEM

(71) Applicant: Max-Planck-Gesellschaft zur Förderung der Wissenschaften e.V., München (DE)

(72) Inventors: Wolfgang Braun, Bietigheim-Bissingen (DE); Thomas J. Smart, Stuttgart (DE)

(21) Appl. No.: 19/132,418

(22) PCT Filed: Nov. 24, 2022
(86) PCT No.: PCT/EP2022/083171

§ 371 Date: May 23, 2025

(51) Int. Cl. C23C 14/28; C23C 14/24; C23C 14/54

(52) U.S. Cl. CPC C23C 14/28; C23C 14/246; C23C 14/54

(57) ABSTRACT

The invention relates to a method of using a thermal laser evaporation (TLE) system. The TLE system comprises a reaction chamber fillable with a reaction atmosphere. A substrate is arranged in the reaction chamber, and one or more sources are arranged in the reaction chamber. Each source comprises a source element having a source material, and a laser source for providing a heating laser beam impinging with a heating spot on a top surface of the source element, thereby evaporating or sublimating the source material from an active area on the top surface of the source element. This provides a flux of evaporated or sublimated source material for a deposition onto the substrate.

The invention relates to a method of using a thermal laser evaporation (TLE) system, the TLE system comprising a reaction chamber fillable with a reaction atmosphere, a substrate arranged in the reaction chamber, one or more sources arranged in the reaction chamber, each source comprising a source element consisting of a source material, and a laser source for providing a heating laser beam impinging with a heating spot on a top surface of the source element and thereby evaporating or sublimating the source material from an active area on the top surface of the source element for providing a flux of evaporated or sublimated source material for a deposition onto the substrate. Further, the invention relates to a respective TLE system, the TLE system comprising a reaction chamber fillable with a reaction atmosphere, a substrate arranged in the reaction chamber, one or more sources arranged in the reaction chamber, each source comprising a source element consisting of a source material, and a laser source for providing a heating laser beam impinging with a heating spot on a top surface of the source element and thereby evaporating or sublimating the source material from an active area on the top surface of the source element for providing a flux of evaporated or sublimated source material for a deposition onto the substrate.

In thermal laser evaporation (TLE), source material is evaporated and/or sublimated in a controlled environment, in particular in a reaction chamber filled with a reaction atmosphere, by means of laser heating, usually with the intent to coat a substrate likewise arranged in the reaction chamber.

In most of the cases, a uniform coating of the substrate is desired. Normally, this at least requires a temporally constant directional intensity distribution of the flux from evaporated or sublimated source material. However, such a directional intensity distribution is strongly dependent on a three-dimensional shape of the top surface of the source element, which is the origin of the evaporated and/or sublimated material.

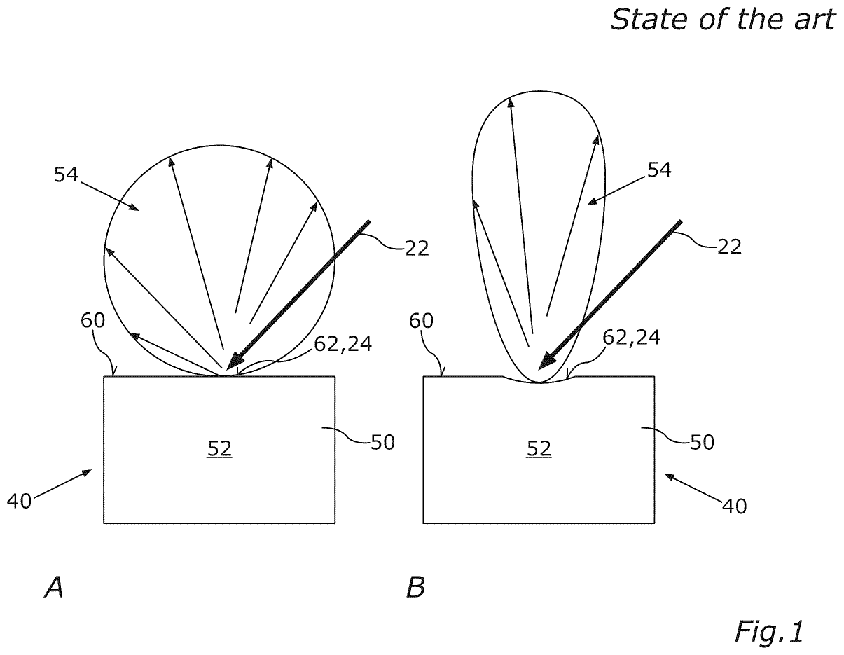

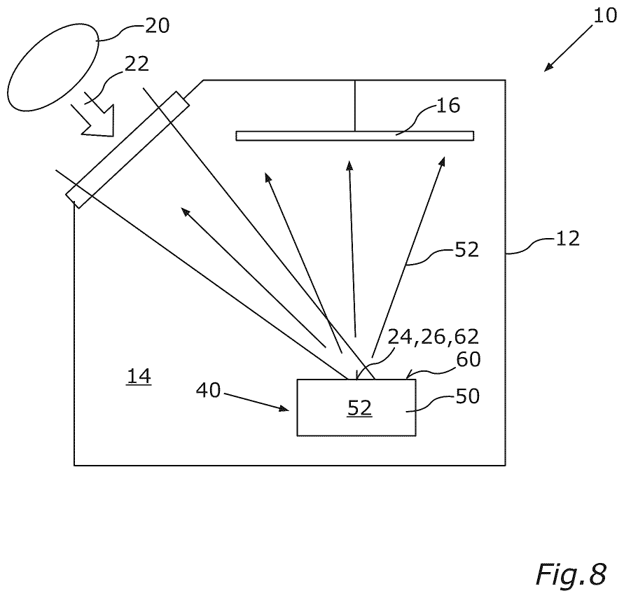

Unfortunately, the three-dimensional shape of said top surface changes over time as the evaporation and/or sublimation of source material locally depletes the source element. This is depicted in FIG. 1, whereas subfigure A on the left depicts an evaporation of source material 52 of a source element 50 at an earlier stage, subfigure B on the right at a later stage. In both stages, a heating laser beam 22 impinges onto a top surface 60 of the source element 50 consisting of source material 52. From an active area 62 source material 52 is sublimated forming a flux 54 of sublimated source material 52. It is clearly visible that a directional intensity distribution of the flux 54, denoted by arrows, at the beginning, when the top surface 60 and hence the active area 62 is flat (subfigure A), strongly differs from the respective directional distribution of the flux 54 at a later stage, when source material 52 is depleted and the active area 62 forms a dipped portion of the top surface 60 (subfigure B). This change in the directional intensity distribution of the flux ultimately leads to a change in the deposition of the sublimated source material 52 on the substrate 16 (see FIG. 8). Thereby a quality of the deposition and consequently of the coated substrate 16 can be significantly reduced.

In view of the above, it is an object of the present invention to provide an improved method of using a thermal laser evaporation system and an improved thermal laser evaporation system which do not have the aforementioned drawbacks of the state of the art. In particular, it is an object of the present invention to provide an improved method of using a thermal laser evaporation system and an improved thermal laser evaporation system, which allow stable deposition of evaporated and/or sublimated source material onto a substrate, in particular wherein a selected directional intensity distribution of a flux of evaporated or sublimated source material can be provided over an elongated time period, preferably be provided continuously.

This object is satisfied by the respective independent patent claims. In particular, this object is satisfied by a method of using a thermal laser evaporation system according to independent claim 1 and by a thermal laser evaporation system according to independent claim 28. The dependent claims describe preferred embodiments of the invention. Details and advantages described with respect to a method according to the first aspect of the invention also refer to a thermal laser evaporation system according to the second aspect of the invention, and vice versa, if of technical sense.

According to the first aspect of the invention, the object is satisfied by a method of using a thermal laser evaporation (TLE) system, the TLE system comprising a reaction chamber fillable with a reaction atmosphere, a substrate arranged in the reaction chamber, one or more sources arranged in the reaction chamber, each source comprising a source element consisting of a source material, and a laser source for providing a heating laser beam impinging with a heating spot on a top surface of the source element and thereby evaporating or sublimating the source material from an active area on the top surface of the source element for providing a flux of evaporated or sublimated source material for a deposition onto the substrate, wherein the method comprises a step of providing a selected directional intensity distribution of the flux of evaporated or sublimated source material by actively adjusting a three-dimensional shape of the active area.

The method according to the first aspect of the present invention is intended for the usage of a thermal laser evaporation system, or short of a TLE system. In particular, the scope of the present invention is a TLE system in which the laser is used for evaporating or sublimating a source material. Such systems are known in general. A heating laser beam provided by a laser source is used for evaporating or sublimating the source material, in most of the cases for a deposition of the evaporated or sublimated source material onto a substrate provided as target. The source material is provided as source element arranged in a source within the reaction chamber, wherein one or more sources are possible, in particular providing different source materials. The heating laser beam impinges at a heating position onto a top surface of the source element, whereas the heating laser beam illuminates a heating spot on said top surface. The actual evaporation or sublimation takes place at an active area of the top surface, wherein the active area is linked to the heating spot and can even be identical to the heating spot. Originating from the active area, a flux of evaporated or sublimated source material is provided comprising a directional intensity distribution of the flux depending on the three-dimensional shape of the active area.

The source is arranged within a reaction chamber, which is sealable against ambient atmosphere and fillable with a reaction atmosphere. Said reaction atmosphere can be vacuum, in particular as low as 10⁻¹² hPa or even lower, or comprise reaction gases at pressures suitable for the material to be deposited, for instance a reaction gas providing oxygen for a deposition of an oxide of evaporated and/or sublimated elemental or compound source material. Maximum values tested with a working distance of 60 mm so far are as high as 10⁻² hPa. Still higher values are likely possible as deposition was possible without problems at 10⁻² hPa.

In most of the cases, at least the main part of the laser source is arranged outside of the reaction chamber and the heating laser beam is coupled into the reaction chamber via coupling means. Said coupling means can be for instance simple windows in a chamber wall of the reaction chamber. However, coupling means according to the present invention can also comprise adaptive optics for forming the heating laser beam impinging on the top surface of the source element.

In the method according to the first aspect of the present invention, the three-dimensional shape of the active area is actively adjusted. An active adjustment in the sense of the present invention encompasses all ways of influencing said three-dimensional shape, both before, and in particular during the evaporation or sublimation process. The adjustment of the active area can also be provided by an active adjustment of the top surface, as the active area is an intrinsic part of the top surface.

There are many different types and ways of adjusting the three-dimensional shape, for instance by accordingly choosing a size of the source element and a size of the heating laser beam, and/or compensating material depletion by the ongoing evaporation or sublimation. Said ways of adjusting the three-dimensional shape can be implemented singular or in combination. Also, ways and measures suitable for evaporation processes can differ from ways and measures suitable for sublimation processes. In general, by adjusting the three-dimensional shape, a selected three-dimensional shape of said active area can be provided. An active adjustment allows providing said three-dimensional shape also during the evaporation or sublimation process, preferably at all times during said process.

As already mentioned above, the directional intensity distribution of the flux depends, in particular strongly depends, on the three-dimensional shape of the active area. In summary, by actively adjusting the three-dimensional shape of the active area, a selected directional intensity distribution of the flux of evaporated or sublimated source material can be provided during the operation of the TLE system.

Thereby, a stable deposition of evaporated and/or sublimated source material onto the substrate can be provided.

Further, the method according to the present invention can comprise that the three-dimensional shape of the active area is adjusted by actively choosing and/or altering
a size of the heating spot with respect to the size of the top surface and/or the size of the active area, and/or
a position of the heating spot on the top surface, and/or
a spatial intensity distribution of the heating laser beam, and/or
a time structure of the intensity of the heating laser beam.

This list is not complete and can be expanded by further suitable ways and measures for actively adjusting the three-dimensional shape of the active area.

In addition, the method according to the present invention can be characterized in that adjusting the three-dimensional shape of the active area is carried out repeatedly, in particular continuously. Repeatedly in the sense of the present invention encompasses repetition rates of 100 mHz or lower, up to 10 MHz or higher. In other words, during the evaporation or sublimation process the repeated or even continuous execution of the active adjusting is provided. By this, also a provision of the selected three-dimensional shape of the active area can be repeatedly, preferably continuously, ensured during the evaporation or sublimation process. Thereby, also the directional flux of the evaporated or sublimated source material can be provided with its selected properties, repeatedly or even continuously.

In addition, the method according to the present invention can comprise that the selected directional intensity distribution of the flux comprises a constant time dependence or at least a periodic time dependence. In particular, a flux with a periodic time dependence can also be considered as constant if considered averaged over one or more period lengths. A flux with a directional intensity distribution constant or at least periodic over time allows a very precise deposition of material onto the substrate. In particular, a thickness of the deposition of source material onto a specific position on the substrate depends mainly on the constant flux of material impinging onto said position and the time duration of the deposition. An overall time dependence of the flux of source material can be avoided. Hence, a stable deposition of evaporated and/or sublimated source material onto the substrate can be enhanced.

According to a first alternative of embodiments of the method according to the present invention, the method can comprise that the flux is provided by sublimation from the solid state by the heating laser beam, and wherein the size of the heating spot is adjusted identical to or larger than the size of the top surface for providing the entire top surface as active area for sublimating source material. By this, the lateral size of the top surface, and hence of the active area, is both limited and simultaneously defined by the boundaries of the source element. During the sublimation process, a steady state establishes which is defined by controllable boundary conditions such as the parameters of the heating laser beam, the size of the top surface and a consequently self-establishing temperature profile in the source element. Hence, the flux of sublimated source material can be provided constant over time, and thereby a stable deposition of sublimated source material onto the substrate can be provided.

In addition, the method can be enhanced by that the source comprises an actuator for moving the source element, and whereby the source element is moved for keeping the spatial position of the active area constant with respect to the heating laser beam and the substrate for compensating a material loss due to the sublimated source material. During the sublimation process, source material is slowly removed from the active area the top surface, respectively, and hence from the source element. As consequence, the spatial position of the active area with respect to both the impinging heating laser beam and the substrate slightly changes over time. For instance, a distance between the active area and the substrate grows. By using an actuator of the source for moving the source element, said material loss can be compensated and the relative spatial position of the active area with respect to both the heating laser beam and the substrate, can be kept constant over time. In the aforementioned example, the source element is moved towards the substrate with a pace accordingly chosen to the sublimation rate of the source material. A change of the directional intensity distribution of the flux of evaporated source material due to material loss can thereby be avoided.

Alternatively, or additionally, also the heating laser beam itself can be moved for keeping the spatial position of the active area constant with respect to the heating laser beam and the substrate for compensating a material loss due to the sublimated source material. For instance, optical elements such as mirrors and/or lenses can be used for moving the position of the heating laser beam. In general, all advantages described above with respect to an actuator for moving the source element can also be provided by said respective optical elements for moving the heating laser beam.

In a second alternative embodiment, the method according to the present invention can be characterized in that the heating laser beam melts the source material for forming the active area as a pool of molten source material and evaporates source material from the pool and thereby the flux of source material is provided, and wherein the size of the heating spot is adjusted smaller than the size of the top surface for forming the pool and thereby the active area with a selected size and a selected curvature. The curvature of such a pool of molten source material contained by the remaining and still solid source material of the source element is given, e.g., by a surface tension of the molten source material, the density of and gravitational force acting on the molten source material, and temperature gradients imposed by the heating laser beam and developing within the material, with the possibility of driving convection currents that themselves affect the shape of the surface.

The curvature of the surface of the pool, and hence of the active area, reproducibly depends via these parameters on the diameter and shape of the surface boundary line between liquid and solid, and the contact angle at this boundary. In most of the cases, for a given source material and intensity of the heating laser beam to achieve a given deposition rate, the size of the pool of molten source material is fixed, Hence, said curvature of the active area, namely the surface of the pool, and thereby the directed density distribution of the flux of the evaporated source material can easily be controlled. In summary, also in this embodiment of the method according to the present invention the directional intensity distribution of the flux of evaporated source material can be provided in a selected and chosen way, and thereby a stable deposition of evaporated source material onto the substrate can be provided.

Additionally, the method according to the present invention can be enhanced further by that the size of the heating spot is adjusted by accordingly adjusting the intensity distribution of the heating laser beam, in particular with respect to an overall intensity and/or a spatial distribution and/or a size and/or a position and/or a shape of the intensity distribution of the heating laser beam. This list is not complete and can be expanded by further suitable ways and measures for actively adjusting the intensity distribution of the heating laser beam. In other words, the size of the heating spot can be actively selected by providing a heating laser beam which intensity distribution comprises accordingly adjusted properties.

According to a first implementation of a third and again alternative embodiment of the method according to the present invention, the heating laser beam melts the source material for forming the active area as a pool of molten source material and evaporates source material from the pool and thereby the flux of source material is provided, and wherein the size of the heating spot is adjusted identical to or larger than the size of the top surface for forming a pool of molten source material on the entire top surface as active area, and wherein the intensity of the heating laser beam is adjusted for forming the pool and thereby the active area with a selected curvature. In contrast to the embodiment described in the previous paragraph, now the size of the heating spot is chosen such that the complete top surface of the source element is not only illuminated by the heating laser beam but also melted.

In a second implementation of the third embodiment of the method according to the present invention, the heating laser beam melts the source material for forming the active area as a pool of molten source material and evaporates source material from the pool and thereby the flux of source material is provided, and wherein the intensity of the heating laser beam is adjusted for forming a pool of molten source material on the entire top surface as active area, and wherein the intensity of the heating laser beam is further adjusted for forming the pool and thereby the active area with a selected curvature. Analogous to the first implementation of the third embodiment, also according to the second implementation of the third embodiment of the method according to the present invention a pool of molten source material is formed on the entire top surface as active area. In contrast to the first implementation, said melting of the entire top surface is provided by sufficiently increasing the intensity of the laser beam and thereby ensuring that enough laser energy is absorbed by the source element for said melting of the entire top surface.

In other words, according to both implementations of the third embodiment of the method according to the present invention, the pool of molten source material stretches over the complete top surface and the active area is identical to the top surface. Once the rim of the pool of molten source metal reaches the edge of the source element, and hence the outer rim of the to surface, the surface of the pool usually becomes convex, in the extreme a floating drop with a contact angle exceeding 90°. However, the size of the drop can easily be controlled by accordingly choosing the intensity of the heating laser beam. Thereby, different curvatures of the active area can easy be selected and adjusted by accordingly setting the intensity of the heating laser beam. In other words, as the directional intensity distribution of the flux of evaporated source material strongly depends on the curvature of the emitting surface, said directional intensity distribution can also be provided in a selected and chosen way, allowing a stable deposition of evaporated source material onto the substrate.

Further, the method according to the present invention can be enhanced by that the pool comprises a flat on average curvature. Preferably, this condition can be provided by providing a source element with a flat upper end and by setting the intensity of the heating laser beam such that only a thin film of molten source material is present at said upper end of the source element, covering the top surface and simultaneously forming the active area. Thereby, the shape of the surface of the active area mostly follows the flat shape of the upper end of the source element, and only at the rim high curvature values occur. In general, by providing the pool of molten source material pool with a flat on average curvature, the directed intensity distribution of the flux of evaporated source material can be also be provided with an extended region of constant flux. Thereby, a stable and especially uniform deposition of evaporated source material onto the substrate can be provided.

In addition, the method according to the present invention can be again enhanced by that the source comprises an actuator for moving the source element, and whereby the source element is moved for keeping the spatial position of the active area constant with respect to the heating laser beam and the substrate for compensating a material loss due to the evaporated source material. Also, during the evaporation process, source material is removed from the active area the top surface, respectively, and hence from the source element. Likewise to the respective description above with respect to a sublimation process, again the spatial position of the active area with respect to both the impinging heating laser beam and the substrate changes over time. By using an actuator of the source for moving the source element, said material loss can be compensated and the relative spatial position of the active area with respect to both the heating laser beam and the substrate, can be kept constant over time. A change of the directional intensity distribution of the flux of evaporated source material due to material loss can thereby be avoided.

In an alternative fourth embodiment of the method according to the present invention, the method can be characterized in that the source comprises a crucible and the source element is provided in the crucible, and wherein the heating laser beam completely melts the source material in the crucible for forming the active area as a pool of molten source material at the entire top surface and evaporates source material from the pool and thereby the flux of source material is provided, and wherein a crucible material of the crucible is chosen with respect to the source material for forming the pool and thereby the active area with a selected curvature.

Molten source material inside the crucible forms a contact angle with the crucible material. The contact angle in the sense of the present invention, also known as wetting angle, is measured inside the source material at the contact line in the plane locally perpendicular to the contact line. In particular, a small contact angle will usually lead to a concave surface of the molten source material and hence the active area, while a large contact angle will lead to a convex surface of the active area. In other words, the contact angle has a strong influence on the curvature of the active area.

Said contact angle strongly depends on both the source material and the crucible material, respectively. For metallic source materials inside an oxide crucible, for instance gallium in a sapphire crucible, this contact angle is usually large. Metals or semiconductors as source material in a crucible made of a metallic crucible material, for instance germanium in a tantalum crucible, typically have a small contact angle. Consequently, for source materials for which different suitable crucible materials exist, this mechanism can be exploited to control the contact angle and hence the curvature. In summary, by accordingly choosing the crucible material, a curvature of the active area and hence a directed intensity distribution of the flux of evaporated source material can actively be selected.

Further, the method according to the present invention can comprise that the three-dimensional shape of the crucible is accordingly chosen for providing the selected curvature. As mentioned above, the contact angle is measured inside of the source material at the contact line. The contact line is defined as the line at which the molten source material separates from the crucible. In other words, one leg of the contact angle runs along the exposed surface of the molten source material, the other leg along the crucible wall enclosing the molten source material. Thereby, by accordingly choosing the three-dimensional shape of the crucible, the contact angle can directly be influenced. A curvature of the active area and hence a directed intensity distribution of the flux of evaporated source material can thereby be actively chosen.

In addition, the method according to the present invention can be enhanced further by that the crucible is completely filled or overfilled due to the surface tension thereof with the source material. In other words, the contact line, which defines the contact angle and hence the curvature, coincides with an upper rim of the crucible and hence is geometrically fixed by and to said rim of the crucible. Further, a wide variety of source materials comprise a large surface tension in their respective molten state, thereby allowing strong overfilling of the crucible. As the contact line stays geometrically fixed to the rim of the crucible, this leads to a change in the overall convex curvature of the active area, in particular selectable by the amount of overfilling the crucible.

Alternatively, or additionally, the method according to the present invention can also be enhanced by that the heating spot is smaller than the top surface and the active area, respectively, and wherein a heating position of the heating spot at the active area is chosen with respect to the local curvature of the active area at said heating position.

For a large amount of source material inside a crucible with large diameter, gravity will usually win over surface tension and produce a melt with a top surface that is very close to planar and horizontal at its center. This is usually also the preferred position for the heating spot of the heating laser beam for forming the active area at this high symmetry point. This leads to a directional intensity distribution of the flux of evaporating source material with high spatial uniformity.

Nevertheless, by using geometries of the heating laser beam asymmetric with respect to the center of the crucible, the highest temperature point and therefore the active area, can also be shifted to other areas of the top surface. This allows yet another way to control the directional intensity distribution of the flux via the curvature of the top surface, as the top surface comprises a position depended curvature and the position of the active area within the top surface can be actively selected by accordingly positioning the heating position of the heating spot.

According to an alternative fifth embodiment, the method according to the present invention can comprise that the step of providing a selected directional intensity distribution of the flux of evaporated source material comprises a preparation step and a subsequent evaporation step, wherein in the preparation step the three-dimensional shape of the entire top surface is formed, whereby the three-dimensional shape of the active area as part of the top surface is provided with respect to the selected directional intensity distribution of the flux, and in the evaporation step the heating laser beam evaporates and/or sublimates source material from the active area.

As already described above, the three-dimensional shape of the active area strongly influences the directional intensity distribution of the flux of evaporated source material originating from said active area. Hence, by actively forming said three-dimensional shape of the top surface, and hence automatically also of the active area as intrinsic part of the top surface, a flux of evaporated and/or sublimated source material comprising a selected directional intensity distribution can be provided.

In the preparation step, said forming of the top surface is provided. The forming process can include any process capable of altering a three-dimensional shape such as machining, ablation, sintering, but also melting and subsequent controlled solidification. In particular, the most suitable forming process can be selected for the respective source, for instance considering the source material and/or a size of the source element as a whole, of the top surface, and/or of the active area, respectively.

In the subsequent evaporation step, the laser beam impinges onto the top surface of the source element such that at the intended active area source material is evaporated and/or sublimated. As the active area, prepared in the preparation step, comprises a specific three-dimensional shape adapted to the intended and selected directional intensity distribution of the flux of evaporated and/or sublimated source material, said flux can be automatically be provided with said directional intensity distribution. Hence, also by this embodiment of the method according to the present invention, a stable deposition of evaporated and/or sublimated source material onto the substrate can be provided.

In addition, the method according to the present invention can be enhanced by that in the preparation step a shaping laser beam impinging with a shaping spot on the top surface of the source element is used for adjusting the three-dimensional shape of the top surface, wherein the shaping laser beam is used for melting the source material and/or for providing a controlled solidification of the molten source material. During the melting by the shaping laser, in particular source elements arranged in a crucible can be melted completely or only partly. For sources without crucibles, and hence with self-supporting source elements, only the source material of the top surface or even only parts of the top surface such as the active area and/or its surroundings, are melted to a certain depth into the source element. The shaping spot of the shaping laser can accordingly cover the whole top surface or only parts of the top surface such as in particular the active area.

A controlled solidification in the sense of the present invention encompasses any measures which allow taking influence on the three-dimensional shape of the top surface during solidification. By using the shaping laser during the solidification, the time sequence of the solidification can be influenced. In other words, some spots on the top surface solidify prior to other spots, in particular where the shaping laser impinges onto the latter spots for preventing premature solidification. Additionally, differences in the density of the molten and solid states of the source material can be exploited here to influence the resulting three-dimensional shape of the top surface as desired. In summary, by using a shaping laser for the preparation step, a wide variety of possible three-dimensional shapes of the top surface can be provided.

According to a further enhancement of the method according to the present invention, a shape of the shaping spot and/or a position of the shaping spot on the top surface are accordingly adjusted for providing the controlled solidification of the molten source material. A shape in the sense of the present invention not only encompasses for instance a circular or elliptical shape of the shaping spot, but also a shaping spot fragmented into two or more separated sub spots and/or including local intensity minima within the shaping spot, for instance a ring-shaped shaping spot. Also, a movement of the shaping spot of the shaping laser, effectively forming a time-averaged area in which the shaping laser acts on the source material, is a shaping spot in the sense of the present invention. Hence during the controlled solidification, the time sequence of the solidification can be influenced especially easily, in particular in combination with the afore-mentioned exploitation of differences in density variations of the molten and solid source material, respectively.

For instance, if the source material in its solid state comprises a higher density compared to its molten state, a shaping laser impinging onto a single shaping spot during the beginning of the solidification process effectively leads to a mound- or tip-like three-dimensional shape of the top surface, comprising a locally convex curvature. The other way around, a shaping laser impinging onto a ring-shaped shaping spot during the beginning of the solidification process effectively leads to ring-shaped mound and hence to a dip in middle of the three-dimensional shape of the top surface, comprising a locally concave curvature.

Further, the method according to the present invention is characterized in that the heating laser beam for evaporating and/or sublimating the source material from the active area of the source element in the evaporation step is used as shaping laser beam in the preparation step. In other words, the laser source provides a laser beam which can be uses as both heating laser beam and shaping laser beam, respectively. Parameters of the respective laser beam, such as overall intensity, beam direction, intensity distribution, time structure and/or repetition rate, can be identical or different during its usage as heating laser beam and shaping laser beam, respectively. In summary, by using the same laser beam for both heating and shaping, respectively, the overall setup of the TLE system constructed to carry out the method according to the present invention can be simplified.

In addition, the method according to the present invention can comprise that the preparation step and the subsequent evaporation step are carried out alternately and repeatedly. As already mentioned above, due to the evaporation process material loss occurs and hence the actual three-dimensional shape of the active area may change over time. By stopping the evaporation step and re-doing the preparation step, this change in three-dimensional shape of the active area can be controlled and reversed. Hence the advantage of an evaporation originating from an actively selected three-dimensional active area, in particular, after subsequently restarting the evaporation step, and thereby the provision of a selected directional intensity distribution of the flux of evaporated source material, can be provided over an extended time period.

The method according to the present invention can be enhanced further by that during the repeated execution of the preparation step and the subsequent evaporation step, the reaction chamber remains closed and filled with the reaction atmosphere. As described above, the reaction chamber of the TLE system is filled with a reaction atmosphere during carrying out the method according to the present invention. Providing said reaction atmosphere can be quite complex, with respect to both cost, time, and/or work expended, respectively. In particular, the reaction atmosphere is often provided as a flow equilibrium in which the feeding of gaseous components of the reaction atmosphere into the reaction chamber and the pumping of these gaseous components out of the reaction chamber are simultaneous and adapted to each other. This allows a reaction atmosphere to be provided at a selected pressure. By keeping the reaction chamber closed during the repeated execution of the preparation step and the subsequent evaporation step, aeration of the reaction chamber by the ambient atmosphere can be avoided. The reaction atmosphere already present in the reaction chamber remains enclosed in the reaction chamber. In other words, providing said reaction atmosphere again after each repetition can be avoided.

Further, the method according to the present invention can be characterized in that the source comprises re-feeding means for re-feeding additional source material into the pool for at least compensating a material loss due to the evaporated source material. As already described above, the evaporation process leads to material loss of the source element and hence a shift in the position of the top surface with respect to the heating laser beam and the substrate. Additionally, or alternatively to providing an actuator for moving the source element, also re-feeding additional source material into the pool can be used for at least time-averaged keeping the top surface at a fixed position within the reaction chamber.

Re-feeding means are used for putting the additional source material into the pool, where the additional source material subsequently is melted by the heating laser beam and hence replaces the evaporated source material. By that a level of the pool can be kept constant, at least time-averaged kept constant. Also, a, preferably slight, overcompensation of the material loss is possible. In summary, the directional intensity distribution of the flux of evaporated source material and hence a stable deposition of evaporated source material onto the substrate can be provided.

Additionally, the method according to the present invention can be enhanced by that the re-feeding means periodically re-feeds the additional source material into the pool. In other words, after a certain time period additional source material is fed into the pool and thereby re-fills the pool. This leads to a periodic directional intensity distribution of the flux of evaporated source material, fluctuating around a time-averaged mean value. Preferably, said time periods are suitably chosen such that the time-averaged mean value is the selected directional intensity distribution, for instance by the aforementioned slight overcompensation of the material loss. Further, said time periods are preferably also suitably chosen such that the fluctuations are both small in absolute flux values with respect to the mean value, and in period length with respect to the time needed for the intended deposition process in total, or with a period length corresponding to an essentially exact integer fraction of the deposition time.

Alternatively, the method can also be characterized in that the re-feeding means continuously re-feeds the additional source material into the pool. By continuously re-feeding additional source material into the pool a constant position of the top surface, provided by the surface of the pool, with respect to the heating laser beam and the substrate can be continuously be provided. Hence, a flux of evaporated source material with a constant selected directional intensity distribution can be provided.

In addition, the method according to the present invention can comprise that the additional source material is provided as a wire, in particular wherein the reaction chamber comprises a differentially pumped feedthrough for feeding the wire to the re-feeding means. As wires can be provided with very long extensions, a time period in which the evaporation process can be provided in the TLE system can be extended by providing the additional source material in the form of a wire. In particular, if the wire additionally is provided through a differentially pumped feedthrough from outside the reaction chamber, said time period is basically not limited.

Also, the method according to the present invention can be enhanced by that the additional source material is re-fed into the pool distanced to a maximum intensity of the heating spot of the heating laser beam and/or at a rim of the pool. The maximum of the evaporation process is located at the maximum intensity of the heating spot of the laser beam away from a rim of the pool. Hence, the directional intensity distribution of the flux of evaporated source material is dominated by source material evaporated from said region of the active area. By re-feeding the additional source material distanced to said maximum intensity of the heating spot of the heating laser beam and/or at the rim of the pool, an influence of the refeeding process to the evaporation process can be minimized.

According to the second aspect of the invention, the object is satisfied by a thermal laser evaporation (TLE) system, the TLE system comprising a reaction chamber fillable with a reaction atmosphere, a substrate arranged in the reaction chamber, one or more sources arranged in the reaction chamber, each source comprising a source element consisting of a source material, and a laser source for providing a heating laser beam impinging with a heating spot on a top surface of the source element and thereby evaporating or sublimating the source material from an active area on the top surface of the source element for providing a flux of evaporated or sublimated source material for a deposition onto the substrate. The TLE system according to the present invention is constructed to carry out the method according to one of the preceding claims. By that, the thermal laser evaporation system according to the second aspect of the present invention provides all features and advantages described above with respect to a method according to the first aspect of the present invention.

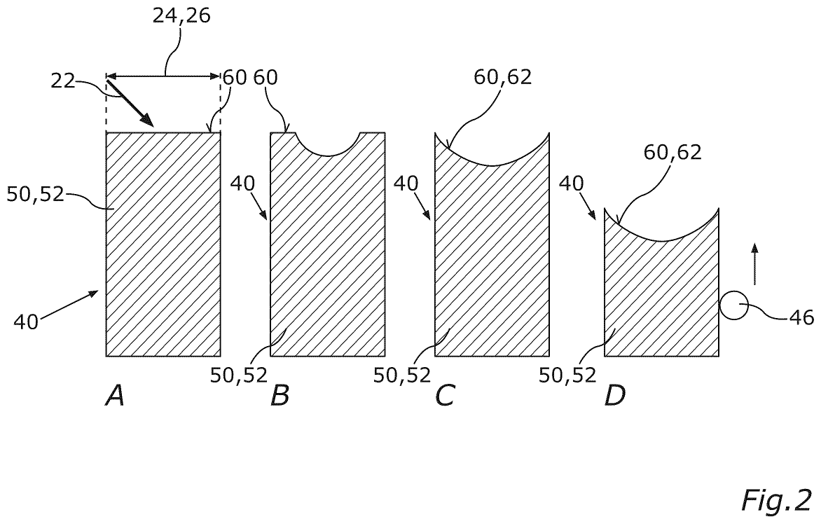

The invention will be explained in detail in the following by means of embodiments and with reference to the drawings. The method according to the present invention allows a stable deposition of evaporated and/or sublimated source material onto a substrate. This is provided by ensuring that the flux of evaporated or sublimated source material comprises a selected directional intensity distribution, preferably over a prolonged time period, in particular continuously. In the following, possible embodiments and enhancements of said method according to the present invention are described according their schematic visualization in FIGS. 2 to 7. In FIG. 8, a TLE system constructed to carry out the method according to the present invention is shown.

In particular, in the figures are shown:

FIG. 1 Schematic views of a directed intensity distribution of a flux of evaporated source material according to the state of the art,

FIG. 2A first embodiment of the method according to the present invention,

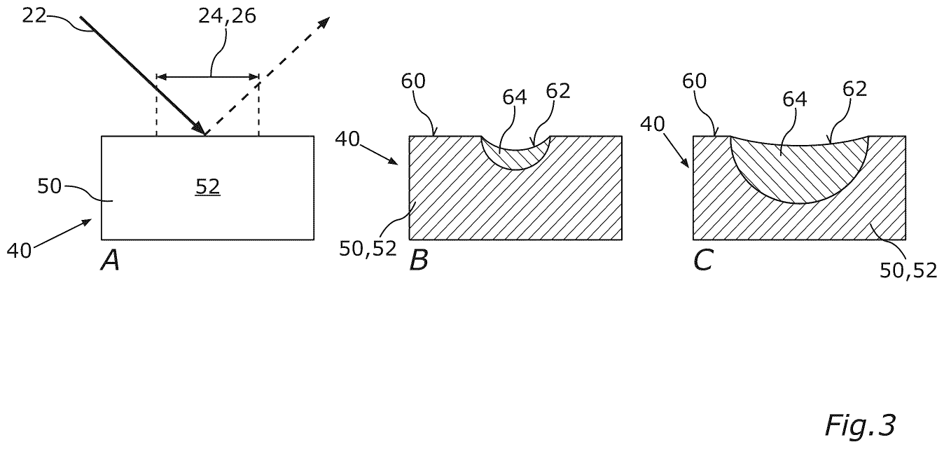

FIG. 3A second embodiment of the method according to the present invention,

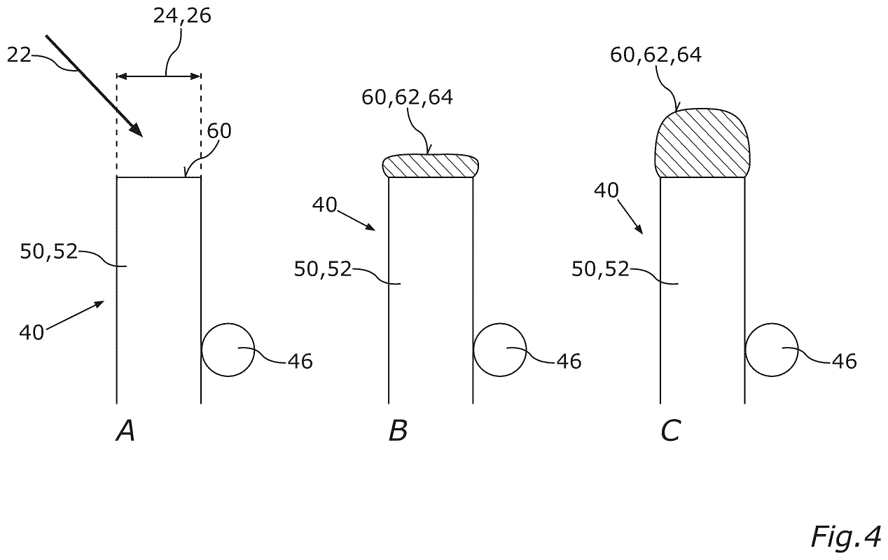

FIG. 4A third embodiment of the method according to the present invention,

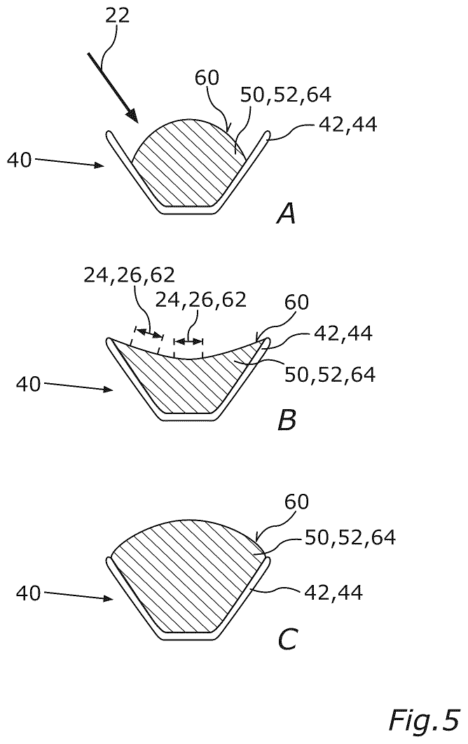

FIG. 5A fourth embodiment of the method according to the present invention,

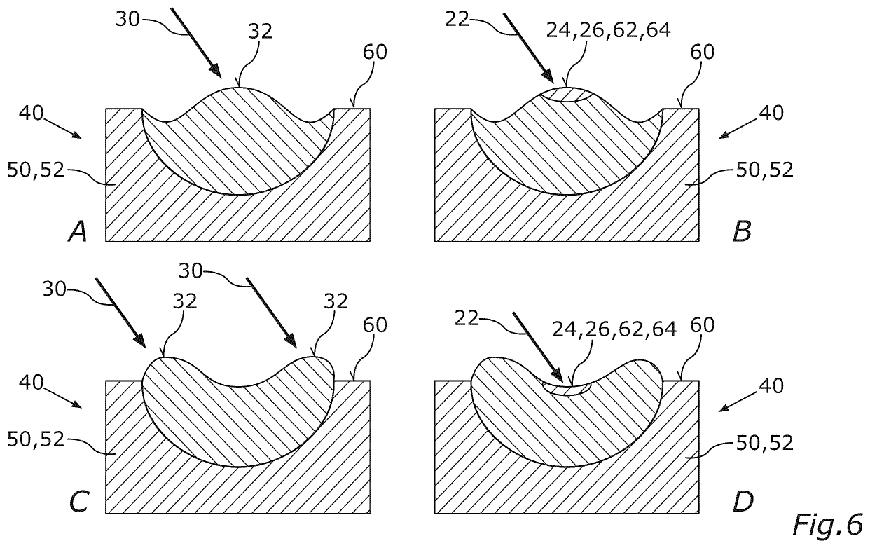

FIG. 6A fifth embodiment of the method according to the present invention,

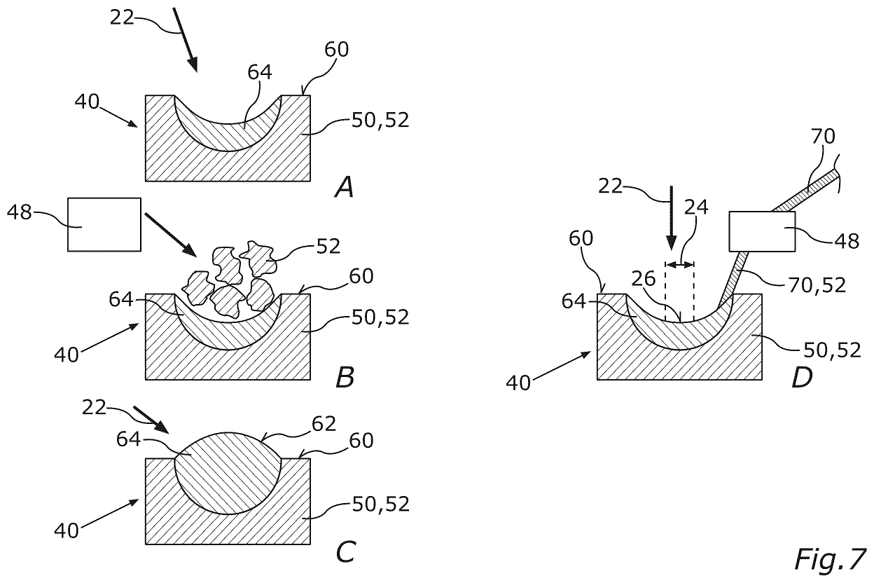

FIG. 7 An enhancement of the method according to the present invention, and

FIG. 8A schematic view of a thermal laser evaporation system according to the present invention.

In general, the different embodiments of the method according to the present invention described in the following are presented at a fixed point in time. However, for providing a stable deposition of evaporated and/or sublimated source material 52, a continuous or at least repeated execution of the respective measures of the depicted methods according to the present invention is of advantage.

In FIG. 2, a sublimation of source material 52 from a self-supporting source element 50 used as source 40 is shown. In subfigure A, a beginning of the sublimation process is depicted. A heating laser beam 22 provided by a laser source 20 (see FIG. 8) impinges onto a top surface 60 of the source element 50. The size of the heating laser beam 22 is chosen such that the heating spot 24 of the heating laser beam 22 on the source element 50 encompasses the entire top surface 60.

Hence, the actual heating position 26 is of secondary relevance.

Subfigure B shows an intermediate state of the sublimation process. Some of the source material 52 was already sublimated, forming a dip in the top surface 60. However, as the heating spot 24 (see subfigure A) encompasses the entire top surface 60, further sublimation of source material 52 will both deepen the dip and widen the dip, respectively, until source material 52 is sublimated from the entire top surface 60.

This phase is depicted in subfigure C. The entire top surface 60 is used for the sublimation of source material 52. In other words, the entire top surface 60 forms the active area 62. Decisive for the depicted embodiment of the method according to the present invention is that the three-dimensional shape of the top surface 60, and hence also of the active area 62, persists once this stage is reached, as the size of the top surface 60 is limited by the boundaries of the source element 50. Hence, the selected directional intensity distribution of the flux 54 (see FIG. 8) of the sublimated source material 52, which depends on said three-dimensional shape of the active area 62, can be provided over an extended period of time.

However, after sublimating a sufficiently large quantity of source material 52, the relative position of the top surface 60 with respect to the heating laser beam 22 starts changing, as depicted in subfigure D in an exaggerated manner. For counteracting this, the source 40 preferably comprises an actuator for accordingly moving the source element 50. By that, the aforementioned change of the relative position of the top surface 60 with respect to the impinging heating laser beam 22 due to material loss caused by sublimating source material 52 can be counteracted. Preferably, the movement of the source element 52, depicted in subfigure D as an arrow next to the actuator 46, is provided such that said material loss is exactly compensated. For this, the movement of the source element 50 provided by the actuator 46 can be preferably continuous or at least periodic.

Starting from FIG. 3, embodiments of the method according to the present invention are shown in which the source material 52 is evaporated by the impinging heating laser beam 22. In all respective embodiments depicted in FIGS. 3 to 6, the heating laser beam 22 is used for at least partly melting the source material 52 for forming a pool 64 of molten source material 52 and subsequently evaporating source material 52 out of said pool 64. In other words, the upper surface of the pool 64 forms the active area 62.

In FIG. 3, the influence of the respective size of the pool 64 on the curvature of the active area 62 is depicted. Subfigure A shows the source element 50 of the source 40 at the beginning of the illumination with the heating laser beam 22. The heating laser beam 22 impinges onto the top surface 60 of the source element 50 at a heating position 26, covering a heating spot 24. The size of said heating spot 24 and/or the power density of the laser beam 22 defines the size of the pool 64 of molten source material 52, whereby said size of the pool 64 can be identical to the size of heating spot 24. Also sizes of the pool 64 different to the size of the heating spot 24 are possible, for instance due to thermal conductivity of the source material 52 and/or convection in the already molten source material 52 of the pool 64. In FIG. 3, the size of said heating spot 24 is chosen such that the resulting size of the pool 64 it is smaller than the complete top surface 60. Thereby, the pool 64 is confined by source material 52 of the source element 50.

This is shown in subfigures B, C. In both subfigures, the assumption is made that in both cases the same absolute amount of source material 52 is already evaporated, and that a density of the source material 52 in its solid state is the same as in its molten state. It is clearly visible that in both cases the curvature is concave and that the curvature of the pool 64 with the smaller size (subfigure B) is higher than the respective curvature of the pool 64 with the larger size (subfigure C). Hence, by actively choosing the size of the heating spot 24, and thereby defining the size of the pool 64 and the active area 62, respectively, a curvature of the active area 62 can actively be selected.

As the directional intensity distribution of the flux 54 (see FIG. 8) of the evaporated source material 52 strongly depends on said curvature as three-dimensional shape of the active area 62, also said flux 54 can be provided with an actively selected directional intensity distribution. For an enhancement of the method according to the present invention counteracting the material loss caused by evaporation of the molten source material 52 from the pool 64, re-feeding additional source material 52 can be provided, as described in detail below with reference to FIG. 7.

Similar to FIG. 3 also FIG. 4 depicts the forming of a pool 64 of molten source material 52 by the illumination with the heating laser beam 22. In contrast to the embodiment described with respect to FIG. 3, now the size of the heating spot 24 is adjusted such that it encompasses at least the entire top surface 60. By that, similar to FIG. 2, the actual heating position 26 is of secondary relevance.

In particular, encompassing the entire top surface 60 by the heating spot 24 leads to formation of a pool 64 of molten source material 52 covering also the entire top surface 64, see subfigures B, C. This can also be achieved by choosing the power density of a laser beam 22 with smaller heating spot 24 high enough, but this is not shown in FIG. 4.

Again, subfigure A depicts a start of the evaporation process, the heating laser beam 22 impinges onto the top surface 60 of the source element 50 of the source, but the pool 64 of molten source material 52 is not formed yet.

Subfigures B, C depict two different possible way of forming said pool 64. In subfigure B, the intensity of the heating laser beam 22, in particular including the spatial intensity distribution of the heating laser beam 22, is adjusted such that the heating laser beam 22 just melts enough source material 52 for covering the top surface 60. Thereby, an in general flat surface of the pool 64 can be provided as active area 62.

Different to that, in the way depicted in subfigure C, the heating laser beam 22 is provided with a higher intensity. Hence, more source material 52 melts and forms a floating drop as pool 64 at the upper end of the source element 50. As is clearly visible, the active area 62 provided by said drop of subfigure C comprises a completely different, in particular convex, curvature than the respective active area 62 linked to the flat surface of the pool 64 shown in subfigure B. Again, the directional intensity distribution of the flux 54 (see FIG. 8) of the evaporated source material 52 strongly depends on said curvature, hence also said flux 54 can be provided with an actively selected directional intensity distribution.

Similar to the embodiment shown in FIG. 2, also in the embodiment of FIG. 4 an actuator 46 can be provided for a compensation of material losses due to the evaporation of source material 52. Thereby, the relative spatial position of the top surface 60, and hence also of the active area 62, with respect to the heating laser beam 22 can be kept constant.

Another possibility for actively adjusting the curvature of the active area 62 is shown in FIG. 5. In contrast to all previously discussed embodiments, now the source 40 comprises a crucible 40 for providing the source element 50. The heating laser beam 22 is used for completely melting the source element 50 into the pool 64 of molten source material 52, whereas the crucible 42 is used for confining said pool 64.

Using a crucible provides several ways of actively adjusting the curvature of the top surface 62 provided by the accessible surface of the pool 64. First of all, a material 44 of the crucible 42 can be chosen with respect to the source material 52 such that a certain contact angle at the edge of the pool 64 is established. By said contact angle together with the size of the pool 64, consequently also a curvature of the top surface 60 can be actively selected. By accordingly choosing the crucible material 44, for some source materials 52 not only the pronouncedness of said curvature can be chosen, but even whether the established curvature is convex or concave, see for instance subfigures A, B.

Further, also filling the crucible 42 up to its rim with molten source material 52 can be used for influencing the curvature of the resulting top surface 60. As the rim defines the spatial confinement of the boundary between crucible 42 and molten source material 52, even an overfilling of the crucible 42 with molten source material 52 is possible, thereby extending the accessible curvature values, see subfigure C.

As the source material 52 preferably is completely molten, in addition also actively adjusting the heating position 26 of the heating spot 24 defines the local curvature of the active area 62, from which the respective flux 54 (see FIG. 8) of evaporated source material 52 originates, as depicted in subfigure B. In said subfigure B, exemplarily two different heating positions 26 are shown at regions of the active area 62 with different curvature. As the energy deposition into the pool 64 of molten source material 52 by the heating laser beam 22 is highest at the respective heating position 26, also the evaporation of source material peaks at said heating positions 26. Thereby a desired directional intensity distribution of the flux 54 of evaporated source material 52 can be selected.

In summary, using a crucible 42 for providing the source element 50 provides several unique possibilities for actively adjusting a curvature of the active area 62 with all respective advantages already described above.

Similar to FIG. 3, please refer to FIG. 7 and the according description below for an enhancement of the method according to the present invention counteracting the material loss caused by evaporation of the molten source material 52 from the pool 64 by re-feeding additional source material 52.

Another possible way of actively adjusting the curvature of the active area 62 is depicted in FIG. 6, wherein subfigures A, B show a first variant and subfigures C, D a second variant of said way. In general, before evaporating source material 52 from a pool 64 of molten source material 52 by the heating laser beam 22 in an evaporation step (subfigures B, D), a preparation step is carried out before to actively provide a selected curvature of the top surface 60 of the source element 50 (subfigures A, C).

For said preparation step a distinct shaping laser beam 30 can be used. However, preferably the heating laser beam 22 (in FIG. 6 not depicted) can also be used as shaping laser beam 30 in the preparation step. A part of the source material 52 (closely hatched) is molten by the shaping laser 30, see subfigures A, C. As depicted, the molten source material 52 can be confined in still solid source material 52 (widely hatched). However, also the usage of crucibles 42 (in FIG. 6 not shown) is possible. Afterwards, the shaping laser beam 30 preferably is used for a controlled solidification of the previously molten source material 52. Depending on a shape of the shaping laser beam 30 and on a shaping spot 32 at which the shaping laser beam 30 impinges on the source element 50, different three-dimensional shapes of the top surface 60 of the source element 50 can be provided, for instance comprising a convex hump (subfigure A) or a concave dip (subfigure C).

In the evaporation step subsequent to the preparation step, the heating position 26 and the size of the heating spot 24 of the heating laser beam 22 is actively selected for choosing the desired curvature on the top surface 60 for establishing the pool 64 whose surface defines the active area 62. In the examples depicted in FIG. 6, actively selecting an evaporation from a convex active area 62 (subfigure B) or from a concave active area 62 (subfigure D) can be provided.

Also in this embodiment, material loss due to evaporation of source material 52 slowly destroys the selected curvature and hence the provision of the selected directional intensity distribution of the flux of evaporated source material 52 is no longer possible. In addition to the enhancement of the method according to the present invention by re-feeding additional source material 52 described below with reference to FIG. 7, also repeating the preparation step and subsequently also the evaporation step is possible. Preferably, the reaction chamber 12 (see FIG. 8) stays closed for said repetitions for avoiding the time, cost and work consuming process of refilling the reaction chamber 12 with the reaction atmosphere 14.

As already mentioned above, material loss due to evaporation of source material 52 slowly destroys any actively adjusted relative position of the top surface 60 of the source element 50 with respect to the heating laser beam 22 and additionally also with respect to the substrate 16 to be coated (see FIG. 8). Subfigure A of FIG. 7 depicts this stage of an evaporation process. A pool 64 of molten source material 52 is confined in the still solid part of the source element 50 of the source, however the surface of the pool 64 forms a deep dip in the top surface 60 with an especially unwanted curvature.

However, as an enhancement of the method according to the present invention additional source material 52 is re-fed into the pool 64 is provided. Hence, at least a compensation of the material loss due to evaporation of molten source material 52 from the pool 64 can be provided. For that, the source 40 comprises re-feeding means 48 for re-feeding the additional source material 52 in to the pool 64, see subfigure B. As depicted, this can be done during an interruption of the evaporation.

After the re-feeding of the additional source material 52, the heating laser 22 is switched back on and all of the re-fed additional source material 52 is also melted, forming again an active area 62 with an actively selected curvature (see subfigure C). As depicted, by carefully selecting the amount of re-fed source material 52 this even allows inversing the curvature of the active area 62. This procedure can be periodically repeated.

Alternatively, and as shown in subfigure D, the additional source material 52 can also be continuously provided by the re-feeding means 48, for instance as a wire 70. By that, also continuously re-feeding the additional source material 52 and compensating the material loss, respectively, can be provided. Preferably, the wire 70 is fed into the reaction chamber 12 (see FIG. 8) through a differentially pumped feedthrough to the re-feeding means 48. By that, a time period in which the evaporation process can be provided without interruption is basically not limited with respect to the evaporated source material 52.

Additionally, and also shown in subfigure D, a preferred location of the re-feeding of the additional source material 52 is at the rim of the pool 64 and hence especially distanced to the heating spot 24 at the heating position 26. Thereby, unwanted influences from the re-feeding process to the evaporation process can be minimized.

FIG. 8 shows a schematic and simplified cross sectional side view of a thermal laser evaporation (TLE) system 10 according to the present invention. The TLE system 10 is constructed to carry out the method according to the present invention. Within a reaction chamber 12, a source 40 providing a source element 50 comprising a source material 52 and a substrate 16 are arranged. The reaction chamber 12 is filled with a reaction atmosphere 14, for instance a vacuum or a suitable reaction gas.

A heating laser beam 22 provided by a laser source 20 is coupled into the reaction chamber 10 for impinging onto the top surface 60 of the source element 50 at a heating position 26 with a heating spot 24. By implementing the method according to the present invention, for instance in one of the embodiments described above with respect to FIGS. 2 to 7, a flux 54 of evaporated and/or sublimated source material 52 can be provided with a selected directional intensity distribution. The quality of the coating of the substrate 16 can thereby be significantly enhanced.

### LIST OF REFERENCES

10 TLE system
12 Reaction chamber
14 Reaction atmosphere
16 Substrate
20 Laser source
22 Heating laser beam
24 Heating spot
26 Heating position
30 Shaping laser beam
32 Shaping spot
40 Source
42 Crucible
44 crucible material
46 Actuator
48 Re-feeding means
50 Source element
52 Source material
54 Flux
60 Top surface
62 Active area
64 Pool
70 Wire

1-28. (canceled)

29. Method of using a thermal laser evaporation system, the TLE system comprising a reaction chamber fillable with a reaction atmosphere, a substrate arranged in the reaction chamber, one or more sources arranged in the reaction chamber, each source comprising a source element consisting of a source material, and a laser source for providing a heating laser beam impinging with a heating spot on a top surface of the source element and thereby evaporating or sublimating the source material from an active area on the top surface of the source element for providing a flux of evaporated or sublimated source material for a deposition onto the substrate,
wherein the method comprises a step of providing a selected directional intensity distribution of the flux of evaporated or sublimated source material by actively adjusting a three-dimensional shape of the active area.

30. Method according to claim 29,
whereby the three-dimensional shape of the active area is adjusted by actively choosing and/or altering
a size of the heating spot with respect to the size of the top surface and/or the size of the active area, and/or
a position of the heating spot on the top surface, and/or
a spatial intensity distribution of the heating laser beam, and/or
a time structure of the intensity of the heating laser beam.

31. Method according to claim 29,
wherein adjusting the three-dimensional shape of the active area is carried out repeatedly.

32. Method according to claim 29,
wherein the selected directional intensity distribution of the flux comprises a constant time dependence or at least a periodic time dependence.

33. Method according to claim 29,
wherein the flux is provided by sublimation from the solid state by the heating laser beam, and wherein the size of the heating spot is adjusted identical to or larger than the size of the top surface for providing the entire top surface as active area for sublimating source material.

34. Method according to claim 33,
wherein the source comprises an actuator for moving the source element, and whereby the source element is moved for keeping the spatial position of the active area constant with respect to the heating laser beam and the substrate for compensating a material loss due to the sublimated source material.

35. Method according to claim 29,
wherein the heating laser beam melts the source material for forming the active area as a pool of molten source material and evaporates source material from the pool and thereby the flux of source material is provided, and wherein the size of the heating spot is adjusted smaller than the size of the top surface for forming the pool and thereby the active area with a selected size and a selected curvature.

36. Method according to claim 35,
wherein the size of the heating spot is adjusted by accordingly adjusting the intensity distribution of the heating laser beam.

37. Method according to claim 29,
wherein the heating laser beam melts the source material for forming the active area as a pool of molten source material and evaporates source material from the pool and thereby the flux of source material is provided, and wherein the size of the heating spot is adjusted identical to or larger than the size of the top surface for forming a pool of molten source material on the entire top surface as active area, and wherein the intensity of the heating laser beam is adjusted for forming the pool and thereby the active area with a selected curvature.

38. Method according to claim 29,
wherein the heating laser beam melts the source material for forming the active area as a pool of molten source material and evaporates source material from the pool and thereby the flux of source material is provided, and wherein the intensity of the heating laser beam is adjusted for forming a pool of molten source material on the entire top surface as active area, and wherein the intensity of the heating laser beam is further adjusted for forming the pool and thereby the active area with a selected curvature.

39. Method according claim 37,
wherein the pool comprises a flat on average curvature.

40. Method according to claim 37,
wherein the source comprises an actuator for moving the source element, and whereby the source element is moved for keeping the spatial position of the active area constant with respect to the heating laser beam and the substrate for compensating a material loss due to the evaporated source material.

41. Method according to claim 29,
wherein the source comprises a crucible and the source element is provided in the crucible, and wherein the heating laser beam completely melts the source material in the crucible for forming the active area as a pool of molten source material at the entire top surface and evaporates source material from the pool and thereby the flux of source material is provided, and wherein a crucible material of the crucible is chosen with respect to the source material for forming the pool and thereby the active area with a selected curvature.

42. Method according claim 41,
wherein the three-dimensional shape of the crucible is accordingly chosen for providing the selected curvature.

43. Method according claim 41,
wherein the crucible is completely filled or overfilled due to the surface tension thereof with the source material.

44. Method according to claim 41,
wherein the heating spot is smaller than the top surface and the active area, respectively, and wherein a heating position of the heating spot at the active area is chosen with respect to the local curvature of the active area at said heating position.

45. Method according to claim 29,
wherein the step of providing a selected directional intensity distribution of the flux of evaporated source material comprises a preparation step and a subsequent evaporation step, wherein in the preparation step the three-dimensional shape of the entire top surface is formed, whereby the three-dimensional shape of the active area as part of the top surface is provided with respect to the selected directional intensity distribution of the flux, and in the evaporation step the heating laser beam evaporates and/or sublimates source material from the active area.

46. Method according to claim 45,
wherein in the preparation step a shaping laser beam impinging with a shaping spot on the top surface of the source element is used for adjusting the three-dimensional shape of the top surface, wherein the shaping laser beam is used for melting the source material and/or for providing a controlled solidification of the molten source material.

47. Method according to claim 46,
wherein a shape of the shaping spot and/or a position of the shaping spot on the top surface are accordingly adjusted for providing the controlled solidification of the molten source material.

48. Method according to claim 46,
wherein the heating laser beam for evaporating and/or sublimating the source material from the active area of the source element in the evaporation step is used as shaping laser beam in the preparation step.

49. Method according to claim 46,
wherein the preparation step and the subsequent evaporation step are carried out alternately and repeatedly.

50. Method according to claim 49,
wherein during the repeated execution of the preparation step and the subsequent evaporation step, the reaction chamber remains closed and filled with the reaction atmosphere.

51. Method according to claim 35,
wherein the source comprises re-feeding means for re-feeding additional source material into the pool for at least compensating a material loss due to the evaporated source material.

52. Method according claim 51,
wherein the re-feeding means periodically re-feeds the additional source material into the pool.

53. Method according claim 51,
wherein the re-feeding means continuously re-feeds the additional source material into the pool.

54. Method according to claim 51,
wherein the additional source material is provided as a wire.

55. Method according to claim 51,
wherein the additional source material is re-fed into the pool distanced to a maximum intensity of the heating spot of the heating laser beam and/or at a rim of the pool.

56. Thermal laser evaporation system, the TLE system comprising a reaction chamber fillable with a reaction atmosphere, a substrate arranged in the reaction chamber, one or more sources arranged in the reaction chamber, each source comprising a source element consisting of a source material, and a laser source for providing a heating laser beam impinging with a heating spot on a top surface of the source element and thereby evaporating or sublimating the source material from an active area on the top surface of the source element for providing a flux of evaporated or sublimated source material for a deposition onto the substrate,
wherein the TLE system is constructed to carry out the method according to claim 29.

57. Method according to claim 56,
wherein the size of the heating spot is adjusted with respect to an overall intensity and/or a spatial distribution and/or a size and/or a position and/or a shape of the intensity distribution of the heating laser beam.

58. Method according to claim 54,
wherein the reaction chamber comprises a differentially pumped feedthrough for feeding the wire to the re-feeding means.
